(19) United States
(12) Patent Application Publication
(10) Pub. No.: US 2023/0164961 A1
(43) Pub. Date: May 25, 2023

(54) ELECTRICAL CIRCUIT DEVICE AND MOTOR VEHICLE

(71) Applicant: AUDI AG, Ingolstadt (DE)

(72) Inventors: Cornelius RETTNER, Lauf a.d. Peg. (DE); Benjamin SÖHNLE, Ingolstadt (DE)

(21) Appl. No.: 18/058,200

(22) Filed: Nov. 22, 2022

(30) Foreign Application Priority Data
Nov. 24, 2021 (DE) 102021130733.3

(51) Int. Cl. H05K 7/20; H02M 7/00; H02G 5/10

(52) U.S. Cl. CPC H05K 7/209; H02M 7/003; H02G 5/10

(57) ABSTRACT

Electrical circuit device comprising a power electronics circuit with at least one power electronics module, a filter device, a heat sink, a connector and at least one busbar, wherein the filter device is at least partially coupled to the busbar and the busbar electrically connects the connector to the power electronics circuit, wherein the power electronics module and at least a portion of the busbar are thermally connected to the heat sink.

### BACKGROUND

### Technical Field

Embodiments of the invention relate to an electrical circuit device comprising a power electronics circuit with at least one power electronics module, a filter device, a heat sink, a connector and at least one busbar, wherein the filter device is at least partially coupled to the busbar and the busbar electrically connects the connector to the power electronics circuit. Furthermore, embodiments of the invention relate to a motor vehicle.

### Description of the Related Art

In motor vehicles with electric drive, one or more electric motors are typically used as traction motors to drive the motor vehicles. Three-phase motors are traditionally used, which are supplied from a direct current energy source, in particular a traction battery, and are controlled by means of an inverter. Such inverters are implemented, for example, as a power electronics circuit consisting of one or more power electronics modules. These can form a common assembly with other elements. In addition to a traction battery, other types of direct current energy sources, for example, a fuel cell or a rectifier connected to an alternating current network, can also be used to supply a traction electric motor.

For filtering interference, especially in a direct current sub-network connected to the inverter, a filter device can be used which can filter, for example, common mode interference or differential mode interference. The interference caused by switching operations during operation of the power electronics circuit can be filtered or alternatively converted into heat by the components of the filter device. The supply of a direct current to the inverter or alternatively the power electronics circuit can also lead to heating of the electrical circuit device. The heating of the components of the filter device may, however, be limited to a maximum permissible temperature, such that depending on the heat input, measures may be required to limit the heating.

For this purpose, it is known to thermally connect the components of the filter device to a housing of the electrical circuit device, for example, in such a manner that heat can be dissipated by means of the housing. This does, however, have the disadvantage that the amount of heat dissipated by means of the housing and thus the heat dissipation of the components depends strongly on the temperature of the housing or the environment of the circuit device. Various approaches are known from the prior art for reducing the heating or alternatively for cooling of components of an electrical circuit device.

In DE 10 2018 208 308 A1, an electrical power converter with a modular filter apparatus for filtering common mode interference and differential mode interference is described. The components for the filter apparatus are cooled by means of a cooling device, which is also used for cooling the power electronic components of the converter, in order to achieve a compact design of the converter.

DE 10 2017 222 024 A1 discloses an inverter with a plate-shaped support device. The body of the support device is configured as a heat sink so that various functional components of the inverter can be cooled by means of the support device. The functional components are arranged on the sides of the support device for this purpose.

A filter component is known from DE 10 2017 113 556 B3, which has a first region for the passage of at least one busbar. Furthermore, the filter component comprises a second region in which at least one discrete component is arranged, wherein the first region and the second region are separated from one another by a cooling region. A thermal decoupling of the first area from the second area is achieved by means of the cooling area, in order to reduce the heating of the discrete component.

### BRIEF SUMMARY

Some embodiments provide an electrical circuit device which has reduced heating of its components, in particular reduced heating of a filter device.

In some embodiments, in an electrical circuit device of the type mentioned above, the power electronics module and at least one section of the busbar are thermally connected to the heat sink.

By thermally connecting at least one section of the busbar to the heat sink, the heating of the filter device can be reduced, since the temperature of the busbar can, in particular, be reduced by the thermal connection to the heat sink. In addition to cooling the power electronics module, the cooler can thereby also cool the busbar. Since the filter device or alternatively its components are connected to the busbar, it is possible that the temperature of the filter device or alternatively its components can also be kept to a minimum.

Some embodiments may be based on the recognition that the main heat input into the filter device is brought about by the heating of the busbars or alternatively the temperature of the connector which is electrically connected to the power electronics circuit by means of the busbars. High supply currents fed to the power electronics circuit by means of the connector can, in particular, lead to considerable heating up of the connector, which is configured, for example, as a direct current plug or alternatively as a DC plug.

The busbars, which generally need to have a considerable current-carrying capacity, are, in particular, made of a conductive metal such as aluminum and/or copper and are therefore also thermally conductive, such that their heating can further contribute to the diffusion of the heat introduced by means of the connector in the electrical circuit device. By way of example, a connector configured as a direct current plug can, for example, reach a temperature of 150° C. when feeding a power electronics circuit configured as an inverter circuit. Such temperatures may be undesirable for individual components of the filter device connected to the busbars, in particular for capacitors and/or inductors, as they may reduce the service life of the components or necessitate the use of more cost-intensive, temperature-stable components.

The thermal connection of at least one section of the at least one busbar to the heat sink makes it possible to use components with a lower permissible maximum temperature, for example, 105° C., since a significant reduction in the temperature of the busbar and thereby also of the filter device or alternatively its components can be achieved due to the heat dissipation from the busbar into the heat sink. In particular, a higher heat input of the connector can be dissipated through the cooling of the at least one busbar, such that the heat from there does not contribute to a heating of the components of the filter device, or at least only to a reduced extent. This can also improve the service life of the components of the filter device.

Furthermore, the thermal connection of the busbar to the heat sink makes it possible to dispense with the use of a further heat sink and/or with a further thermal connection of the filter device or alternatively its components to a housing of the electrical circuit device. This has the advantage that the temperature of the filter device or alternatively its components is not, or at least not significantly, dependent on a housing temperature, such that an environment in which the electrical circuit device is inserted also has no or only a negligible influence on the temperatures of the filter device or alternatively its components. In particular, the components that make up the bodies of the components of the filter device can, for example, be spaced away from a housing of the circuit device by a gap. It is thereby possible, in particular, to dispense with the arrangement of a thermally conductive material, such as a gap filler or a gap pad, between the component and the housing, which can simplify the assembly of the electrical circuit device.

The omission of a thermal connection of components of the filter device to a housing of the circuit device further enables a flexible use of the electrical circuit device, for example, in differently configured electrical axes or in differently configured motor vehicles. By means of the arrangement of the at least one busbar on the heat sink, it is possible that reliable cooling of the busbar can be achieved, since the temperature of a heat sink used for cooling the power electronics module can generally be well below a temperature of a housing of the circuit device during operation of the circuit device.

The thermal connection of the busbar to the heat sink can, for example, be made by direct contact between the busbar and a top surface of the heat sink. An indirect contact, in which the busbar is connected to the top surface of the heat sink, for example, by means of an intermediate layer which is, in particular, thermally conductive and electrically insulating, is also possible. By way of example, a heat-conducting paste, a gap filler, a gap pad or the like can be used as an intermediate layer. The power electronics module can likewise be connected to the top surface of the heat sink directly or by means of an intermediate layer.

The busbar can, for example, be arranged on the side surface of the heat sink on which the at least one power electronics module is also arranged. Such a configuration enables the heat sink to be made only slightly longer for the additional cooling of the at least one busbar in order to thermally connect the at least one busbar to the heat sink in addition to the at least one power electronics module. In addition to the connection of the at least one power electronics module and the at least one busbar to the same side surface, it is also possible for a connection to different side surfaces or alternatively differently oriented sections of the top surface of the heat sink.

In some embodiments, it can be provided that the filter device comprises at least one capacitor connected to the busbar and/or at least one inductance element coupled to the busbar, in particular a ferrite core. The filter device may, in particular, comprise a plurality of differently configured components, by way of example, a combination of one or more capacitors and/or one or more inductance elements.

In some embodiments, it may be provided that the filter device comprises at least one common mode choke, at least one common mode capacitor and/or at least one differential mode capacitor. An inductance element surrounding the busbar, such as a ferrite core, can be used as a common mode choke.

A capacitor of the filter device can be configured, for example, as a common mode capacitor or alternatively a C_{y} capacitor. In this case, the capacitor can be connected, by way of example, with one end to the busbar and with the other end to a ground connector, for example, a housing of the electrical circuit device which is connected to a ground potential. A capacitor configured as a differential mode capacitor or alternatively as a Cₓ capacitor can, for example, be connected between two busbars when they are used. The differential mode capacitor can also have a parasitic inductance which enables its impedance to be influenced in a targeted manner when filtering high-frequency differential mode interference.

In some embodiments, it can be provided that the filter device comprises an inductance element arranged at the connector and/or surrounding the connector. In this context, the inductance element may be configured, for example, as a common mode choke or alternatively as a core for filtering common mode interference and may be referred to as a common mode core. By way of example, a design of the inductance element as a ferrite core is possible.

By arranging the inductance element at the connector or alternatively around the connector, it is possible to avoid electromagnetic interference from the power electronics module into a circuit connected to the connector or alternatively a sub-network arranged at the connector, for example, a direct current sub-network, since the inductance element arranged around the connector can maintain a large distance from the power electronics circuit or the at least one power electronics module. This makes it possible for the current on the busbars, which, in particular, is on a direct current side of the power electronics circuit, to be filtered before leaving the electrical circuit device and, in particular, also for interference coupled in by the heat sink to be filtered out.

The spatial proximity of the inductance element to the connector prevents, in particular, the transmission of interference that could couple into a further filter stage or alternatively a section connected to further components of the filter device between the inductance element at the connector and the power electronics circuit. For this purpose, the inductance element can, in particular, be arranged in such a way that it surrounds the connector, in particular that it at least partially encompasses or alternatively encloses the connector.

In some embodiments, it can be provided that the busbar is thermally connected to the heat sink over at least 50% of its length. In this way, good heat transfer is achieved between the busbar and the heat sink and thus good heat dissipation from the busbar is achieved.

In some embodiments, it may be provided that the heat sink has one or a plurality of cooling channels extending inside the heat sink. In this way, efficient dissipation of even larger amounts of heat from the heat sink or alternatively the parts of the power electronics circuitry connected to the heat sink is enabled. The heat sink can comprise one or a plurality of connectors with which the cooling channel can be connected to a cooling circuit.

In some embodiments, it may be provided that the connector is connected to the power electronics circuit by means of two busbars, the busbars being arranged side by side or one above the other on the heat sink. The busbars can in particular establish a connection of a direct current circuit with the power electronics circuit, such that at least two busbars are required. These busbars can run parallel to one another, in particular while forming a sufficient safety clearance, on a top surface or alternatively on a side surface of the heat sink and be arranged next to or above one another.

Busbars arranged next to each other can be arranged on a side surface of the heat sink in direct contact or indirectly or mediately by means of an intermediate layer on the heat sink. Busbars arranged one above the other can, in particular, be arranged in such a way that a first busbar is indirectly or mediately in contact with the heat sink, wherein the second busbar is arranged on the side of the first busbar opposite the heat sink and is thermally coupled to the first busbar.

At least one thermally conductive and electrically insulating intermediate layer can be provided between the first busbar and the second busbar to enable heat transfer from the second busbar to the first busbar and thereby to the heat sink, and to provide electrical insulation between the two busbars. The intermediate layer can be formed, for example, as a thermally conductive insulation element, a layer of thermal paste, a gap filler, a gap pad or the like.

In some embodiments, it may be provided that the power electronics circuit comprises a direct current link capacitor, wherein the busbars are connected to the direct current link capacitor. The direct current link capacitor can, in particular, also be arranged on the heat sink, such that cooling of the direct current link capacitor is also possible by means of the heat sink. The direct current link capacitor can also be used to filter interference, in particular differential mode interference.

The connection of the direct current link capacitor to the power circuit may occur with as low an inductance as possible, so that the switching operations of the power electronics modules of the power electronics circuit cause no or at least only low switching transients. This enables a high switching speed in the power electronics modules or alternatively in the power electronics circuit.

In some embodiments, the power electronics circuit can be configured as an inverter, in particular, as a multiphase pulse inverter. For this purpose, the power electronics circuit can comprise one or a plurality of power electronics modules, by way of example, three power electronics modules configured as half bridges. The power electronics modules can each have one or a plurality of switching elements. Power electronics modules in the form of half bridges can comprise two series-connected switching elements, each in the form of a transistor. The direct current side of the power electronics circuit is connected to the connector by means of the at least one busbar. One or more connectors can be provided on the alternating current side, by means of which the power electronics circuit can be connected to a further device, in particular an electrical machine.

In some embodiments, it is provided that a motor vehicle comprises an electrical circuit device as described herein. The electrical circuit device can, in particular, form a traction inverter of the motor vehicle, by means of which a traction motor of the motor vehicle can be supplied with current. For this purpose, the electrical circuit device can be connected both to the electric machine and to an energy source, by way of example to a direct current energy source such as a traction battery or a fuel cell. It is also possible to configure the energy source as a rectifier connected or connectable to an alternating current network.

All of the advantages and embodiments described above in relation to electrical circuit devices also apply accordingly to motor vehicles and vice versa.

### BRIEF DESCRIPTION OF THE SEVERAL VIEWS OF THE DRAWINGS

Further advantages and details will be apparent from the embodiments described below and from the drawings.

FIG. 1 shows an embodiment of a motor vehicle.

FIG. 2 shows a circuit diagram of an embodiment of an electrical circuit device.

FIG. 3 shows a perspective view of an embodiment of an electrical circuit device.

### DETAILED DESCRIPTION

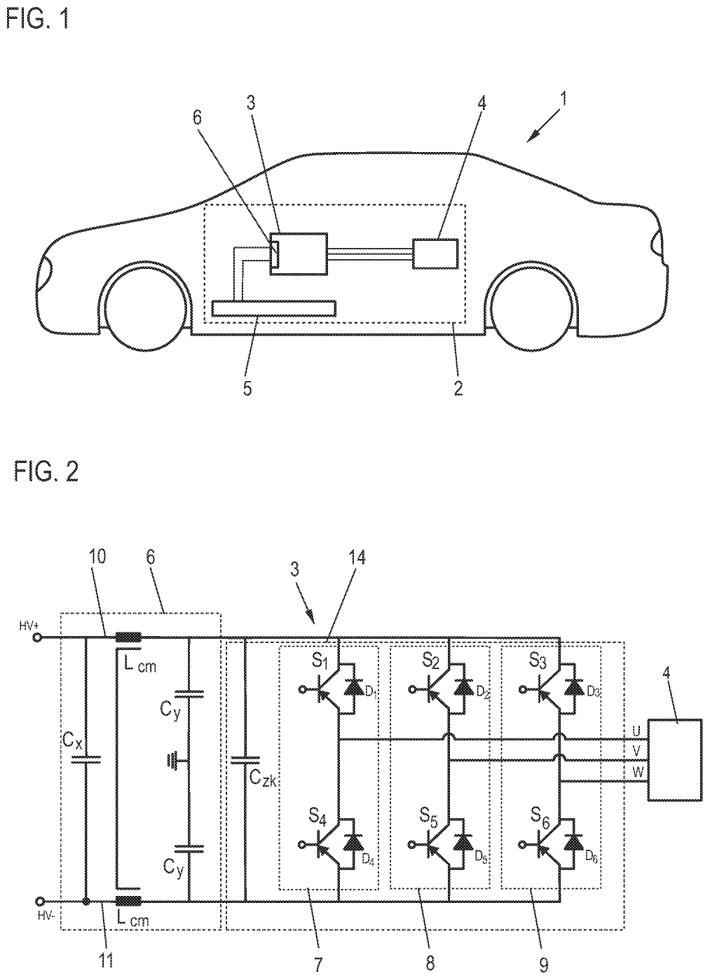

FIG. 1 shows an embodiment of a motor vehicle 1. The motor vehicle 1 comprises an on-board power supply system 2 with an electric circuit device 3, which is connected between an electric machine 4 and an energy storage device 5 of the motor vehicle 1. The electric machine 4 thereby forms a traction electric motor of the motor vehicle 1.

The electrical circuit device 3 is configured as an inverter, such that a direct current taken from the energy storage device 5 can be converted into an alternating current, in particular, a multiphase alternating current, to supply current to the electrical machine 4. Conversely, it is also possible that a rectification of an alternating current generated in a generator mode of the electrical machine 4 can be carried out by the electrical circuit device 3, for example, in a recuperation mode of the motor vehicle 1 for charging the energy storage device 5. The energy storage device 5 can, for example, be configured as a traction battery of the motor vehicle 1. Alternatively, the energy storage device 5 may be configured as a fuel cell or as a rectifier connected or connectable to an alternating current network.

The electrical circuit device 3 may, for example, be configured as a three-phase pulse inverter, the operation of which may cause electrical interference. The electrical circuit device 3 therefore comprises a filter device 6 with which interference occurring on the direct current side of the electrical circuit device 3 during operation of the electrical circuit device 3 can be filtered. The filter device 6 therefore contributes to reduce the alternating current load in the direct current sub-network of the on-board power supply 2.

FIG. 2 shows a circuit diagram of an embodiment of the electrical circuit device 3. The circuit device 3 comprises the filter device 6, a power electronics circuit 14 comprising three power electronics modules 7, 8, 9, as well as two busbars 10, 11. The power electronics modules 7, 8, 9 of the power electronics circuit 14 each comprise two switching elements S₁-S₆, which are connected within a power electronics module 7, 8, 9 in the form of a half bridge. The switching elements S₁-S₆ are configured, for example, as transistors. A freewheeling diode D₁-D₆ is connected in parallel to each of the switching elements S₁-S₆ to also enable rectification of an alternating current in a freewheeling mode of the electric machine 4 connected to the bridge points of the half bridges.

The connectors marked HV+ and HV− on the direct current side of the electrical circuit device 3 are connected to a connector 13 (not shown here) of the electrical circuit device 3. The electrical circuit device 3 is connected to the energy storage device 5 by means of the connector 13. The electrical circuit device 3 can, for example, be connected to the energy storage device 5 by means of one or a plurality of further busbars and/or by means of one or a plurality of cables. The filter device 6 comprises a plurality of components which are configured as condensers or alternatively as inductance elements and which form different filter stages of the filter device 6.

To suppress common mode interference, the filter device 6 comprises a common mode choke L_{cm}, which is arranged around the busbars 10, 11. The common mode choke L_{cm} can, for example, be formed as a ferrite core which encompasses the busbars 10, 11.

A common mode capacitor Cₓ, which is connected between the busbars 10, 11, is further provided for filtering common mode interference. The common mode capacitor Cₓ is used, in particular, for filtering high-frequency common mode interference, since low-frequency common mode interference can be filtered, in particular, by means of a direct current link capacitor C_{zk} of the power electronics circuit 3. Furthermore, the filter device 6 comprises two capacitors C_{y} for filtering differential mode interference. The capacitors C_{y} are each connected between one of the busbars 10, 11 and a ground potential.

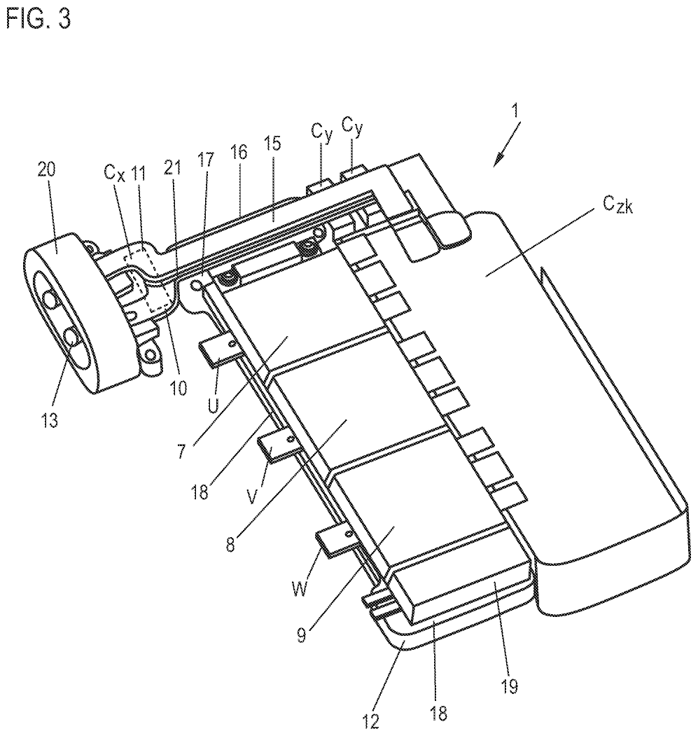

FIG. 3 shows a perspective view of the electrical circuit device 3. The electrical circuit device 3 comprises a heat sink 12 as well as the connector 13. The connector 13 is configured as a direct current plug and forms the direct current connector of the electrical circuit device 3, which is used to connect the electrical circuit device 3 to the energy storage device 5. The connector 13 is connected to the power electronics circuit 14 by means of the busbars 10, 11. The busbars 10, 11 are made of a conductive metal, for example, copper or aluminum, and can also be referred to as conductor bars. In the present case, the connection of the connector 13 is made by means of the busbars 10, 11 to the direct current link capacitor C_{zk} of the power electronics circuit 14.

In this connection, the busbars 10, 11 are each thermally coupled by means of a section 15 of their length to a first section 16 of a top surface 17 of the heat sink 12. The power electronics modules 7, 8, 9 are thermally coupled to a second section 18 of the top surface 17 of the heat sink 12. The direct current link capacitor C_{zk} is likewise thermally coupled to the heat sink 12, wherein in the present case, the coupling occurs to a side surface of the heat sink 12 adjacent to the sections 16, 18.

It is possible that the top surface 17 of the heat sink 12 has one or a plurality of further sections 18 in which, as shown schematically, one or a plurality of further components 19 of the electrical circuit arrangement 14, by way of example sensors, control circuits or the like, can be arranged. The section 16 and the further sections 18 are thereby located on the same side surface of the heat sink 12.

The heat sink 12 may comprise one or a plurality of cooling channels (not shown here) extending inside the heat sink 12. This makes it possible, for example, to connect the heat sink 12 to a cooling circuit of the motor vehicles 1 such that active cooling of the components arranged on the heat sink 12 can take place with the aid of a cooling medium, in particular a liquid cooling medium.

By arranging the busbars 10, 11 in such a way that at least one section 15 of their length is thermally coupled to the heat sink 12, cooling of the busbars 10, 11 by means of the heat sink 12 is enabled. In order to enable good heat dissipation from the busbars 10, 11, the length of the section 15 can correspond in each case to at least 50% of the length of the respective busbar 10, 11.

The components of the filter device 6, for example, the illustrated common mode capacitors C_{y}, are also cooled in this way, since the heat input into the capacitors C_{y} by means of the busbars 10, 11 is reduced. This also applies to other components of the filter device 6, for example, the schematically illustrated differential mode capacitor Cₓ, as well as any further capacitors and/or inductance elements such as coils and/or ferrite cores of the filter device 6 that may be present.

As common mode choke L_{cm}, the filter device 6 further comprises an inductance element 20 which surrounds the connector 13. The connector 13 is thereby at least partially surrounded by the inductance element 20 having an opening, wherein the connector 13 is arranged within the opening of the inductance element 20. The spatially close arrangement of the inductance element 20 at the connector 13 enables filtering, in particular, of interference coupled onto the busbars 10, 11, which is caused by the function of the power electronics modules 7, 8, 9. This interference can also, in particular, couple in in the area of the further filter stages of the filter device 6, which is to say the capacitor Cₓ or alternatively the capacitors Cy, such that they can be filtered by the inductance element 20 through the connector 13 before leaving the electrical circuit device 3. Alternatively to an arrangement of the inductance element 20 around the connector 13, an arrangement directly at or alternatively behind the connector 13 is also possible.

The busbars 10, 11 are arranged one above the other on the heat sink 12. The first busbar 10, which is arranged between the top surface 17 of the heat sink 12 and the second busbar 11, can be in direct contact with the heat sink 12. Alternatively, it is also possible to arrange an intermediate layer between the first busbar 10 and the top surface 17 of the heat sink 12. The intermediate layer can, for example, be a layer of a thermal paste, a gap filler or a gap pad.

An intermediate layer is also arranged between the busbar 10 and the further busbar 11, which intermediate layer is configured as a thermally conductive, electrically insulating insulation element 21. The insulating element 21 electrically insulates the busbars 10, 11 from each other. Due to the thermal conductivity of the insulation element 21, cooling of the further busbar 11 arranged opposite the heat sink 12 on the busbar 10 can also take place. As an alternative to the insulating element 21, an intermediate layer of a heat-conducting paste, a gap filler or a gap pad can also be arranged between the busbars 10, 11.

As an alternative to arranging the busbars 10, 11 one above the other on the first section 16 of the heat sink 12, it is also possible to arrange the busbars 10, 11 next to each other. In this case, both busbars 10, 11 can be in direct contact with the top surface 17 of the heat sink 12 or in indirect or mediate contact by means of an intermediate layer. A gap can remain between the busbars 10, 11 to ensure a sufficient creepage distance between the busbars 10, 11.

The power electronics circuit 3 can have a housing (not shown) which surrounds the components of the electrical circuit device 3 illustrated in FIG. 3. The connector 13 can be accessible from outside the housing, such that a connection of the power electronics circuit 3, in particular with the energy storage device 5, is possible.

Due to the cooling of the busbars 10, 11 by the thermal connection of their section 15, which in particular corresponds to at least 50% of the length of the busbars 10, 11, a thermal connection of the components of the filter device 6, or alternatively a thermal connection of the components that make up the bodies of the components of the filter device 6, with the housing can be dispensed with. This facilitates the assembly of the electrical circuit device 3 and has the particular effect that the temperatures of the components of the filter device 6 do not depend, or at least do not depend significantly, on a temperature of the housing or alternatively on an environment of the electrical circuit device 3. Moreover, by means of the cooling of the busbars 10, 11 it is possible to dispense with the use of special high-temperature building elements as components of the filter device 6.

It is possible that the busbars 10, 11 and/or the power electronics modules 7, 8, 9 are arranged at sections 16, 18, which are located at different side surfaces of the heat sink 12. By way of example, the busbars 10, 11 can also be arranged on a side surface of the heat sink 12 opposite the power electronics modules 7, 8, 9.

German patent application no. 10 2021 130733.3, filed Nov. 24, 2021, to which this application claims priority, is hereby incorporated herein by reference, in its entirety.

Aspects of the various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. An electrical circuit device, comprising:
a power electronics circuit with at least one power electronics module,
a filter device,
a heat sink,
a connector, and
at least one busbar,
wherein the filter device is at least partially coupled to the busbar and the busbar electrically connects the connector to the power electronics circuit,
wherein the power electronics module and at least a portion of the busbar are thermally connected to the heat sink.

2. The electrical circuit device according to claim 1, wherein the filter device has at least one capacitor connected to the busbar and/or at least one inductance element coupled to the busbar.

3. The electrical circuit device according to claim 2, wherein the at least one inductance element is a ferrite core.

4. The electrical circuit device according to claim 2, wherein the filter device comprises at least one common mode choke, at least one common mode capacitor and/or at least one differential mode capacitor.

5. The electrical circuit device according to claim 1, wherein the filter device comprises an inductance element arranged at the connector and/or surrounding the connector.

6. The electrical circuit device according to claim 1, wherein the busbar is thermally bonded to the heat sink over at least 50% of its length.

7. The electrical circuit device according to claim 1, wherein the connector is connected to the power electronics circuit by two busbars, the busbars being arranged next to one another or one above the other on the heat sink.

8. The electrical circuit device according to claim 1, wherein the power electronics circuit comprises a direct current link capacitor, wherein the busbars are connected to the direct current link capacitor.

9. The electrical circuit device according to claim 1, wherein the heat sink has one or more cooling channels extending inside the heat sink.

10. The electrical circuit device according to claim 1, wherein the power electronics circuit is configured as an inverter.

11. The electrical circuit device according to claim 1, wherein the power electronics circuit is configured as a multiphase pulse inverter.

12. A motor vehicle comprising an electrical circuit device according to claim 1.
